(19) United States
(12) Patent Application Publication
(10) Pub. No.: US 2025/0267791 A1
(43) Pub. Date: Aug. 21, 2025

(54) WIRING SUBSTRATE

(71) Applicant: SHINKO ELECTRIC INDUSTRIES CO., LTD., Nagano-shi (JP)

(72) Inventor: Teruaki CHINO, Nagano-shi (JP)

(21) Appl. No.: 19/046,857

(22) Filed: Feb. 6, 2025

(30) Foreign Application Priority Data
Feb. 19, 2024 (JP) 2024-022954

(51) Int. Cl. H05K 1/11; H05K 3/40

(52) U.S. Cl. CPC H05K 1/115; H05K 3/4038; H05K 2201/09563; H05K 2201/096

(57) ABSTRACT

A wiring substrate includes a first wiring layer located on an upper surface of a first insulating layer, a second insulating layer located on the first insulating layer and covering the first wiring layer, a via hole extending through the second insulating layer in a thickness-wise direction and exposing the first wiring layer, and a trench recessed from an upper surface of the second insulating layer. The wiring substrate further includes a via wiring filling the via hole, a conductive layer filling the trench, and a second wiring layer electrically connected to the first wiring layer by the via wiring and located on the upper surface of the second insulating layer. The trench does not extend through the second insulating layer in the thickness-wise direction. The trench is arranged peripheral to the via hole and separated from the via hole. The trench overlaps the second wiring layer in plan view.

### CROSS-REFERENCE TO RELATED APPLICATIONS

This application is based upon and claims the benefit of priority from Japanese Patent Application No. 2024-022954, filed on Feb. 19, 2024, the entire contents of which are incorporated herein by reference.

### BACKGROUND

### 1. Field

This disclosure relates to a wiring substrate and a method for manufacturing a wiring substrate.

### 2. Description of Related Art

Wiring substrates for mounting electronic components, such as semiconductor elements, have various shapes and structures. Japanese Laid-Open Patent Publication No. 2021-168348 discloses a wiring substrate formed by a build-up process that alternately stacks wiring layers and insulating layers. The wiring layers are electrically connected to one another by a via wiring formed in via holes extending through the insulating layers in a thickness-wise direction.

### SUMMARY

In the above described wiring substrate, there is a need for avoiding occurrence of short circuiting between adjacent wiring layers.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a wiring substrate includes a first insulating layer, a first wiring layer, a second insulating layer, a via hole, a trench, a via wiring, a conductive layer, and a second wiring layer. The first wiring layer is located on an upper surface of the first insulating layer. The second insulating layer is located on the upper surface of the first insulating layer and covers the first wiring layer. The via hole extends through the second insulating layer in a thickness-wise direction and exposes an upper surface of the first wiring layer. The trench is recessed from an upper surface of the second insulating layer. The via wiring fills the via hole and is electrically connected to the first wiring layer. The conductive layer fills the trench. The second wiring layer is electrically connected to the first wiring layer by the via wiring and is located on the upper surface of the second insulating layer. The trench does not extend through the second insulating layer in the thickness-wise direction. The trench is located peripheral to the via hole and separated from the via hole. The trench overlaps the second wiring layer in plan view.

Other features and aspects will be apparent from the following detailed description, the drawings, and the claims.

### BRIEF DESCRIPTION OF THE DRAWINGS

FIG. 1 is a schematic cross-sectional view of a wiring substrate in accordance with an embodiment (cross-sectional view taken along line 1-1 in FIG. 3).

FIG. 2 is an enlarged view of part of the wiring substrate in FIG. 1.

FIG. 3 is a schematic cross-sectional view of part of the wiring substrate in FIG. 1 (cross-sectional view taken along line 3-3 in FIG. 2).

FIG. 4 is a cross-sectional view taken along line 4-4 in FIG. 3.

FIG. 5 is a schematic cross-sectional view illustrating a manufacturing step of the wiring substrate in FIG. 1.

FIG. 6 is a schematic cross-sectional view illustrating a manufacturing step of the wiring substrate following the step of FIG. 5.

FIG. 7A is a schematic plan view illustrating a manufacturing step of the wiring substrate following the step of FIG. 6.

FIG. 7B is a cross-sectional view taken along line 7b-7b in FIG. 7A.

FIG. 8A is a schematic plan view illustrating a manufacturing step of the wiring substrate following the step of FIG. 7A.

FIG. 8B is a cross-sectional view taken along line 8b-8b in FIG. 8A.

FIG. 9 is a schematic cross-sectional view illustrating a manufacturing step of the wiring substrate following the step of FIG. 8A.

FIG. 10 is a schematic cross-sectional view illustrating a manufacturing step of the wiring substrate following the step of FIG. 9.

FIGS. 11 and 12 are schematic cross-sectional views illustrating an example of a step of forming a resist layer.

FIG. 13A is a schematic plan view illustrating a manufacturing step of the wiring substrate following the step of FIG. 10.

FIG. 13B is a cross-sectional view taken along line 13b-13b in FIG. 13A.

FIG. 14A is a schematic plan view illustrating a manufacturing step of the wiring substrate following the step of FIG. 13A.

FIG. 14B is a cross-sectional view taken along line 14b-14b in FIG. 14A.

FIG. 15 is a schematic cross-sectional view illustrating a manufacturing step of the wiring substrate following the step of FIG. 14A.

FIGS. 16, 17, and 18 are schematic cross-sectional views illustrating various types of modifications of the wiring substrate.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

An embodiment will now be described with reference to the accompanying drawings.

The drawings may not be drawn to scale, and the relative size, proportions, and depiction of elements may be exaggerated for clarity, illustration, or convenience. In the cross-sectional views, hatching lines may not be illustrated or may be replaced by shadings to facilitate understanding of the cross-sectional structures. In the plan views, hatching lines may be added to some of the members to facilitate understanding of the planar shape of each member. Each drawing indicates an X-axis, a Y-axis, and a Z-axis, which are orthogonal to each other. Each drawing indicates a first direction X1 that extends toward one side along the X-axis, and a first opposite direction X2 that extends toward another side opposite to the first direction X1. Each drawing indicates a second direction Y1 that extends toward one side along the Y-axis, and a second opposite direction Y2 that extends toward another side opposite to the second direction Y1. Each drawing indicates a third direction Z1 that extends toward one side along the Z-axis, and a third opposite direction Z2 that extends toward another side opposite to the third direction Z1. In this specification, the term “plan view” refers to a view of a subject taken in a direction parallel to the Z-axis, unless otherwise specified. In this specification, the term “planar shape” refers to a shape of a subject as viewed in a direction parallel to the Z-axis, unless otherwise specified. In this specification, the term “face” is used to indicate that surfaces or members are located in front of each other. In this case, the surfaces or members do not have to be entirely in front of each other and may be partially in front of each other. The term “face” is also used in this specification to describe a case in which two members are separated from each other and a case in which two members are in contact with each other. In the description of the present disclosure, a numerical range of “X1 to X2” defined by the lower limit value X1 and the upper limit value X2 refers to a range that is greater than or equal to X1 and less than or equal to X2, unless otherwise specified.

### Overall Structure of Wiring Substrate 10

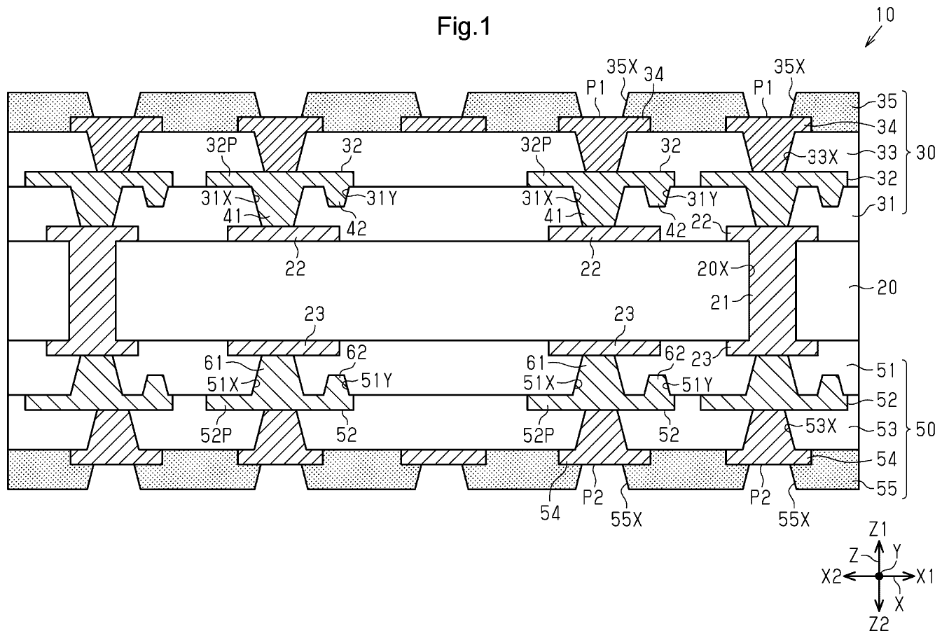

As illustrated in FIG. 1, a wiring substrate 10 includes a core substrate 20, a wiring structure 30 arranged on an upper surface of the core substrate 20, and a wiring structure 50 arranged on a lower surface of the core substrate 20.

The core substrate 20 may be, for example, a glass epoxy substrate formed by impregnating a glass cloth (glass woven cloth), which is a reinforcing material, with a thermosetting resin, which includes an epoxy resin as a main component, and then curing the resin.

The core substrate 20 includes a plurality of through holes 20X extending through the core substrate 20 in a thickness-wise direction. A through-electrode 21 is arranged in the through holes 20X and extends through the core substrate 20 in the thickness-wise direction.

A wiring layer 22 is located on the upper surface of the core substrate 20. A wiring layer 23 is located on the lower surface of the core substrate 20. The wiring layers 22 and 23 are electrically connected to each other by the through-electrode 21. The material of the through-electrode 21 and the wiring layers 22 and 23 may include, for example, copper (Cu) or a copper alloy. The wiring layer 22 and 23 may each have a thickness of, for example, approximately 5 μm to 20 μm.

The wiring structure 30 has a structure in which an insulating layer 31, a wiring layer 32, an insulating layer 33, a wiring layer 34, and a solder resist layer 35 are sequentially stacked on the upper surface of the core substrate 20. The material of the insulating layers 31 and 33 may include, for example, a thermosetting insulating resin. The thermosetting insulating resin may include an insulating resin, such as an epoxy resin, a polyimide resin, a cyanate resin, or the like. The insulating layers 31 and 33 may each contain, for example, a filler such as silica or alumina. The insulating layers 31 and 33 may each have a thickness of, for example, approximately 10 μm to 30 μm. The material of the wiring layers 32 and 34 may include, for example, copper or a copper alloy. The wiring layers 32 and 34 may each have a thickness of, for example, approximately 5 μm to 20 μm. The material of the solder resist layer 35 may include, for example, an insulating resin having a photosensitive resin, such as a phenol-based resin, a polyimide-based resin, or the like, as a main component. The solder resist layer 35 may contain, for example, a filler such as silica or alumina. The solder resist layer 35 may have a thickness of, for example, approximately 10 μm to 30 μm.

The insulating layer 31 is located on the upper surface of the core substrate 20 and covers the wiring layer 22. The insulating layer 31 includes a plurality of via holes 31X that extends through the insulating layer 31 in the thickness-wise direction and exposes an upper surface of the wiring layer 22. The insulating layer 31 includes a plurality of trenches 31Y recessed from an upper surface of the insulating layer 31 toward the core substrate 20 (i.e., in the third opposite direction Z2).

The wiring layer 32 is located on the upper surface of the insulating layer 31. The wiring layer 32 is formed integrally with a via wiring 41 arranged in the via holes 31X and is electrically connected to the wiring layer 22 by the via wiring 41. The wiring layer 32 is formed integrally with a conductive layer 42 arranged in the trenches 31Y. The wiring layer 32 includes, for example, pads 32P. The pads 32P overlap the via holes 31X and the trenches 31Y in plan view. The via holes 31X are filled with the via wiring 41. The trenches 31Y are filled with the conductive layer 42. The conductive layer 42 is electrically connected to the wiring layer 32 and is electrically connected to the via wiring 41 through the wiring layer 32.

The insulating layer 33 is located on the upper surface of the insulating layer 31 and covers the wiring layer 32. The insulating layer 33 includes a plurality of via holes 33X that extends through the insulating layer 33 in the thickness-wise direction and exposes an upper surface of the wiring layer 32. The via holes 33X expose parts of an upper surface of the pads 32P of the wiring layer 32.

The wiring layer 34 is located on an upper surface of the insulating layer 33. The wiring layer 34 is formed integrally with a via wiring arranged in the via holes 33X and is electrically connected to the wiring layer 32 by the via wiring.

The solder resist layer 35 is located on the upper surface of the insulating layer 33 and covers the wiring layer 34. The solder resist layer 35 is the outermost insulating layer (here, the uppermost insulating layer) of the wiring substrate 10.

The solder resist layer 35 includes a plurality of openings 35X that exposes parts of an upper surface of the wiring layer 34 as connection pads P1. The connection pads P1 are, for example, pads for connection with an electronic component, such as a semiconductor element or the like.

A surface-processed layer is formed, if necessary, on the upper surface of the wiring layer 34 exposed at the bottom of each opening 35X. Examples of the surface-processed layer may include a gold (Au) layer, a nickel (Ni) layer/Au layer (metal layer in which the Ni layer serves as bottom layer, and the Au layer is formed on the Ni layer), a Ni layer/palladium (Pd) layer/Au layer (metal layer in which the Ni layer serves as bottom layer, and the Pd layer and the Au layer are sequentially formed on the Ni layer), or the like. Further examples of the surface-processed layer may include a Ni layer/Pd layer (metal layer in which the Ni layer serves as bottom layer, and the Pd layer is formed on the Ni layer), a Pd layer/Au layer (metal layer in which the Pd layer serves as bottom layer, and the Au layer is formed on the Pd layer), or the like. The Au layer is a metal layer of Au or a Au alloy. The Ni layer is a metal layer of Ni or a Ni alloy. The Pd layer is a metal layer of Pd or a Pd alloy. Each of the Au layer, the Ni layer, and the Pd layer may be, for example, a metal layer formed by an electroless plating process (electroless plating layer) or a metal layer formed by an electrolytic plating process (electrolytic plating layer). Alternatively, the surface-processed layer may be an organic solderability preservative (OSP) film formed by performing an oxidation-resisting process, such as an OSP process, on the upper surface of the wiring layer 34. The OSP film may be, for example, an organic coating of an azole compound, an imidazole compound, or the like. When a surface-processed layer is formed on the upper surface of the wiring layer 34, the surface-processed layer acts as the connection pads P1.

The wiring structure 50 has a structure in which an insulating layer 51, a wiring layer 52, an insulating layer 53, a wiring layer 54, and a solder resist layer 55 are sequentially stacked on the lower surface of the core substrate 20. The material of the insulating layers 51 and 53 may include, for example, a thermosetting insulating resin. The thermosetting insulating resin may include an insulating resin, such as an epoxy resin, a polyimide resin, a cyanate resin, or the like. The insulating layers 51 and 53 may each contain, for example, a filler such as silica or alumina. The insulating layers 51 and 53 may each have a thickness of, for example, approximately 10 μm to 30 μm. The material of the wiring layers 52 and 54 may include, for example, copper or a copper alloy. The wiring layers 52 and 54 may each have a thickness of, for example, approximately 5 μm to 20 μm. The material of the solder resist layer 55 may include, for example, an insulating resin having a photosensitive resin, such as a phenol-based resin, a polyimide-based resin, or the like, as a main component. The solder resist layer 55 may contain, for example, a filler such as silica or alumina. The solder resist layer 55 may have a thickness of, for example, approximately 10 μm to 30 μm.

The insulating layer 51 is located on the lower surface of the core substrate 20 and covers the wiring layer 23. The insulating layer 51 includes a plurality of via holes 51X that extends through the insulating layer 51 in the thickness-wise direction and exposes a lower surface of the wiring layer 23. The insulating layer 51 includes a plurality of trenches 51Y recessed from a lower surface of the insulating layer 51 toward the core substrate 20 (i.e., in the third direction Z1). The via hole 51X has substantially the same structure as the via hole 31X, and the trench 51Y has substantially the same structure as the trench 31Y.

The wiring layer 52 is located on the lower surface of the insulating layer 51. The wiring layer 52 is formed integrally with a via wiring 61 arranged in the via holes 51X and is electrically connected to the wiring layer 23 by the via wiring 61. The wiring layer 52 is formed integrally with a conductive layer 62 arranged in the trenches 51Y. The wiring layer 52 includes, for example, pads 52P. The pads 52P overlap the via holes 51X and the trenches 51Y in plan view. The via holes 51X are filled with the via wiring 61. The trenches 51Y are filled with the conductive layer 62. The conductive layer 62 is electrically connected to the wiring layer 52 and is electrically connected to the via wiring 61 through the wiring layer 52.

The insulating layer 53 is located on the lower surface of the insulating layer 51 and covers the wiring layer 52. The insulating layer 53 includes a plurality of via holes 53X that extends through the insulating layer 53 in the thickness-wise direction and exposes a lower surface of the wiring layer 52. The via holes 53X expose parts of a lower surface of the pads 52P of the wiring layer 52.

The wiring layer 54 is located on a lower surface of the insulating layer 53. The wiring layer 54 is formed integrally with a via wiring arranged in the via holes 53X and is electrically connected to the wiring layer 52 by the via wiring.

The solder resist layer 55 is located on the lower surface of the insulating layer 53 and covers the wiring layer 54. The solder resist layer 55 is the outermost insulating layer (here, the lowermost insulating layer) of the wiring substrate 10.

The solder resist layer 55 includes a plurality of openings 55X that exposes parts of a lower surface of the wiring layer 54 as external connection pads P2. The external connection pads P2 are connected to external connection terminals (not illustrated) used when mounting the wiring substrate 10 on a mounting substrate, such as a motherboard or the like.

A surface-processed layer is formed, if necessary, on the lower surface of the wiring layer 54 exposed at the bottom of each opening 55X. Examples of the surface-processed layer may include an OSP film or a metal layer, such as a Au layer, a Ni layer/Au layer, a Ni layer/Pd layer/Au layer, a Ni layer/Pd layer, a Pd layer/Au layer, or the like.

In the present example, external connection terminals (not illustrated) are arranged on the lower surface of the wiring layer 54. Alternatively, the wiring layer 54 exposed at the bottom of each opening 55X (or surface-processed layer formed on the lower surface of the wiring layer 54, if any) may be used as external connection terminals.

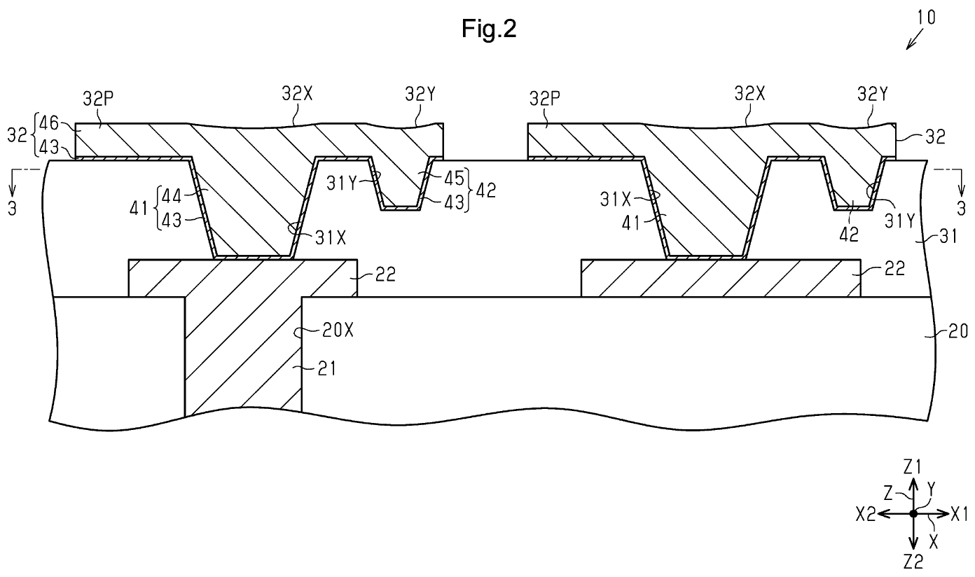

The structures of the via hole 31X, the trench 31Y, the via wiring 41, the conductive layer 42, and the wiring layer 32 will now be described with reference to FIGS. 2 to 4. FIGS. 2 to 4 do not illustrate the insulating layer 33, the wiring layer 34, and the solder resist layer 35, which are located upward from the wiring layer 32.

### Structure of Via Hole 31X

As illustrated in FIG. 2, the via hole 31X exposes part of the upper surface of the wiring layer 22. The via hole 31X is tapered so that the opening width (opening diameter) is decreased from the upper side (i.e., the upper surface of the insulating layer 31) toward the lower side (i.e., the upper surface of the wiring layer 22) in FIG. 2. The wall surface of the via hole 31X is, for example, inclined so that the wall surface becomes closer to the center of the via hole 31X from the upper surface of the insulating layer 31 toward the wiring layer 22 in plan view. The wall surface of the via hole 31X does not have to be straight. Alternatively, the wall surface of the via hole 31X may be partially or entirely curved inwardly or outwardly.

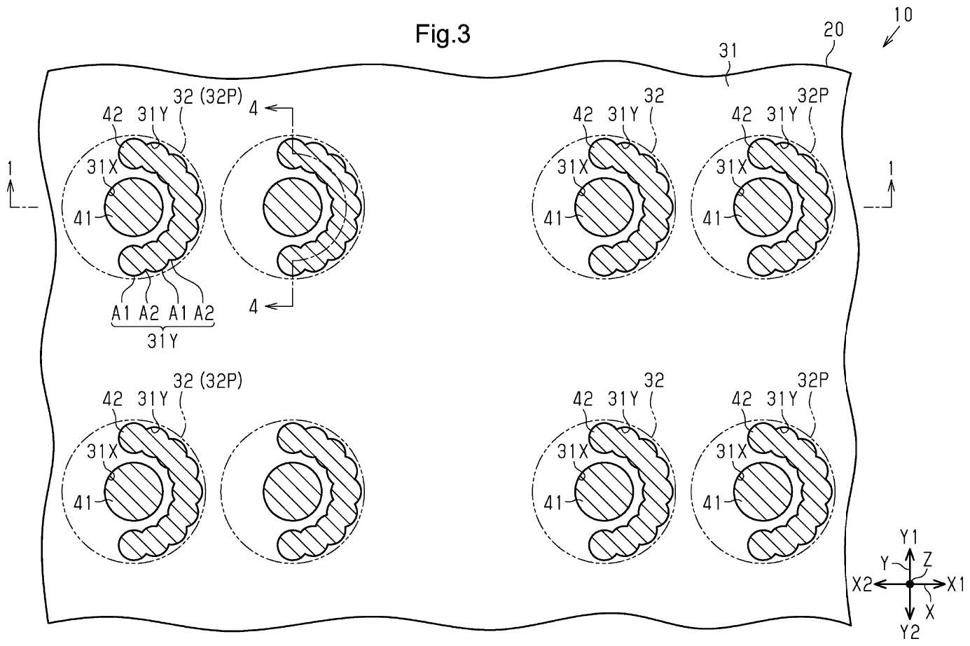

As illustrated in FIG. 3, the via hole 31X has, for example, a circular planar shape. The planar shape of the via hole 31X does not have to be circular and may be any shape. The via hole 31X overlaps the pad 32P of the wiring layer 32 in plan view. The via hole 31X is smaller than the pad 32P in planar size. The via hole 31X is, for example, located at the center of the pad 32P in plan view.

### Structure of Trench 31Y

As illustrated in FIG. 2, the trench 31Y does not extend through the insulating layer 31 in the thickness-wise direction. That is, the trench 31Y does not reach the lower surface of the insulating layer 31. In other words, the bottom surface of the trench 31Y is located in an intermediate part of the insulating layer 31 in the thickness-wise direction. The trench 31Y is shallower than the via hole 31X. The trench 31Y is tapered so that the opening width (opening diameter) is decreased from the upper side (i.e., the upper surface of the insulating layer 31) toward the lower side (i.e., the upper surface of the wiring layer 22) in FIG. 2. The wall surface of the trench 31Y is, for example, inclined so that the wall surface becomes closer to the center of the trench 31Y from the upper surface of the insulating layer 31 toward the core substrate 20 in plan view. The wall surface of the trench 31Y does not have to be straight. Alternatively, the wall surface of the trench 31Y may be partially or entirely curved inwardly or outwardly.

As illustrated in FIGS. 2 and 3, each of the trenches 31Y is arranged for a corresponding one of the via holes 31X. As illustrated in FIG. 3, in the present embodiment, a single trench 31Y is arranged for each of the via holes 31X. Each trench 31Y is arranged peripheral to the corresponding via hole 31X. Each trench 31Y is located proximate to the corresponding via hole 31X. Each trench 31Y is separated from the corresponding via hole 31X. Each trench 31Y is adjacent to the corresponding via hole 31X across the upper surface of the insulating layer 31 in plan view. In an example, a length of the upper surface of the insulating layer 31 from the via hole 31X to the trench 31Y in a radial direction of the via hole 31X in plan view is smaller than a diameter of an upper end of the via hole 31X. Each trench 31Y overlaps the wiring layer 32, which overlaps the corresponding via hole 31X, in plan view. That is, the via hole 31X and the trench 31Y arranged corresponding to the via hole 31X overlap the common wiring layer 32 in plan view.

Each trench 31Y is separated from the corresponding via hole 31X in the first direction X1. Each trench 31Y is separated from the corresponding via hole 31X in a uniform direction (in the example illustrated in FIG. 3, the first direction X1). That is, the direction in which each trench 31Y is separated from the corresponding via hole 31X is set in the same direction (the first direction X1).

Each trench 31Y extends, for example, in the second direction Y1 that is orthogonal to the first direction X1. The trench 31Y has, for example, a dimension in the second direction Y1 that is greater than or equal to a dimension of the via hole 31X in the second direction Y1. The dimension of the trench 31Y in the second direction Y1 is, for example, greater than or equal to the diameter of the via hole 31X. Each trench 31Y faces only part of the circumference of the via hole 31X in plan view. Each trench 31Y continuously faces the circumference of the via hole 31X in plan view. Each trench 31Y continuously faces, for example, the half circumference of the via hole 31X. The term “half circumference” as used in this specification includes not only the perimeter of a semicircle obtained by bisecting a circle but also, for example, an arc that is longer than or shorter than the perimeter of a semicircle. Each trench 31Y may have a planar shape that is arcuate as a whole along the circumference of the via hole 31X. Each trench 31Y has, for example, a semicircular planar shape as a whole along the circumference of the via hole 31X. The lengthwise direction of each trench 31Y coincides with, for example, the circumferential direction of the via hole 31X.

Each trench 31Y has, for example, a contour including projections and recesses in plan view. In the example illustrated in FIG. 3, the contour of the trench 31Y includes projections A1 and recesses A2. The projections A1 and the recesses A2 are alternately arranged one by one. The contour of the projections A1 and the recesses A2 may be arcuate and curved in plan view. The contour of each trench 31Y may be formed by only curves in plan view. In an example, the contour of each trench 31Y includes a number of curves that are continuous with each other in plan view.

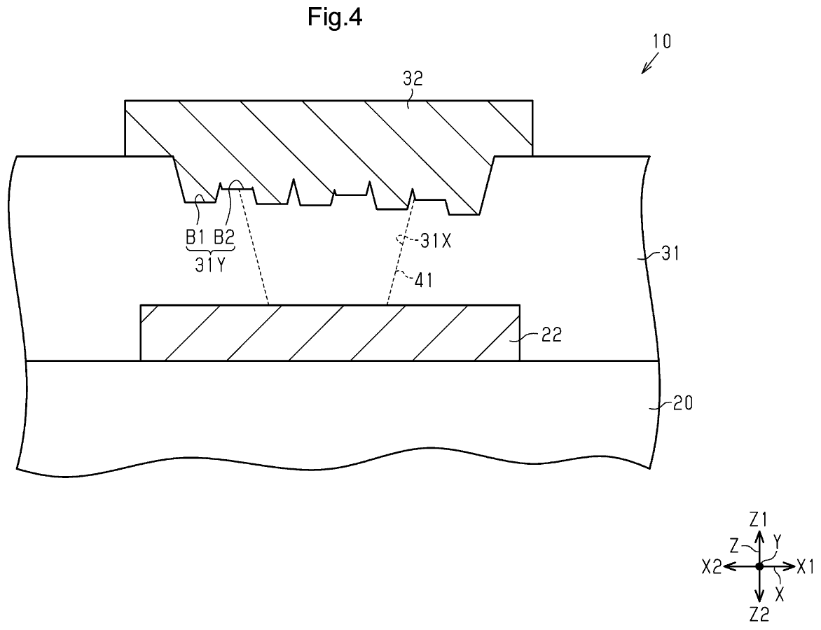

As illustrated in FIG. 4, the bottom surface of each trench 31Y includes irregularities in cross-sectional view. FIG. 4 is a cross-sectional view of the trench 31Y taken in the lengthwise direction of the trench 31Y. FIG. 4 does not illustrate a metal film 43, which will be described later.

Each trench 31Y includes a first trench part B1 and a second trench part B2 that is shallower than the first trench part B1. In each trench 31Y, the first trench part B1 is continuous with the second trench part B2. The bottom surface of the first trench part B1 is located deeper than the bottom surface of the second trench part B2, that is, closer to the core substrate 20. In other words, the bottom surface of the first trench part B1 is offset from the bottom surface of the second trench part B2 in the third opposite direction Z2. The bottom surface of each trench 31Y includes, for example, irregularities formed by steps between the bottom surface of the first trench parts B1 and the bottom surface of the second trench parts B2.

### Structure of Via Wiring 41

As illustrated in FIG. 2, the via wiring 41 fills the via hole 31X. Thus, the via wiring 41 has the shape defined by the via hole 31X. The via wiring 41 includes, for example, a metal film 43 and a metal layer 44. The metal film 43 covers the entire inner surface of the via hole 31X. The metal layer 44 covers the metal film 43 and fills the via hole 31X.

The metal film 43 covers, for example, the entire wall surface of the via hole 31X and the entire upper surface of the wiring layer 22 exposed from the via hole 31X. The metal film 43 is, for example, a seed layer. The material of the metal film 43 may include, for example, copper or a copper alloy. The metal film 43 may be, for example, a metal film formed by an electroless plating process, or an electroless plating film. Alternatively, the metal film 43 may be, for example, a metal film formed by a sputtering process, or a sputtered film. The metal film 43 may have a thickness of, for example, approximately 0.3 μm to 2 μm.

In an example, the metal layer 44 covers the metal film 43 and fills the via hole 31X. The material of the metal layer 44 may include, for example, copper or a copper alloy. The metal layer 44 may be, for example, a metal layer formed by an electrolytic plating process, or an electrolytic plating layer. The metal film 43 and the metal layer 44 located in the via hole 31X form the via wiring 41.

### Structure of Conductive Layer 42

The conductive layer 42 fills the trench 31Y. Thus, the conductive layer 42 has the shape defined by the trench 31Y. The conductive layer 42 includes, for example, the metal film 43 and a metal layer 45. The metal film 43 covers the entire inner surface of the trench 31Y. The metal layer 45 covers the metal film 43 and fills the trench 31Y. The metal film 43 covers, for example, the entire wall surface of the trench 31Y and the entire bottom surface of the trench 31Y.

In an example, the metal layer 45 covers the metal film 43 and fills the trench 31Y. The material of the metal layer 45 may include, for example, copper or a copper alloy. The metal layer 45 may be, for example, an electrolytic plating layer. The metal film 43 and the metal layer 45 located in the trench 31Y form the conductive layer 42.

### Structure of Wiring Layer 32

The wiring layer 32 is located on the insulating layer 31, the via wiring 41, and the conductive layer 42. The wiring layer 32 includes, for example, the metal film 43 and a metal layer 46 located on the metal film 43.

The metal film 43 covers the upper surface of the insulating layer 31 located around the via hole 31X. The metal film 43 covers the upper surface of the insulating layer 31 located around the trench 31Y. The metal film 43 covers the upper surface of the insulating layer 31 located between the via hole 31X and the trench 31Y. In the present embodiment, the metal film 43 continuously covers the upper surface of the insulating layer 31, the wall surface of the via hole 31X, the upper surface of the wiring layer 22 exposed from the via hole 31X, the wall surface of the trench 31Y, and the bottom surface of the trench 31Y.

The metal layer 46 is formed on the via wiring 41 (metal layer 44), the conductive layer 42 (metal layer 45), and the metal film 43 that is formed on the upper surface of the insulating layer 31. The metal layer 46 is formed to be continuous with and integrated with the metal layer 44 and the metal layer 45. The metal layer 45 is formed integrally with the metal layer 44 through the metal layer 46. The material of the metal layer 46 may include, for example, copper or a copper alloy. The metal layer 46 may be, for example, an electrolytic plating layer. The metal film 43 and the metal layer 46 located on the upper surface of the insulating layers 31 form the wiring layer 32.

The upper surface of the wiring layer 32 includes, for example, a dent 32X and a dent 32Y. The dents 32X and 32Y are recessed from the upper surface of the wiring layer 32 toward the core substrate 20. For example, the dent 32X overlaps the via hole 31X in plan view. The dent 32X has, for example, an arcuate and curved surface. For example, the dent 32Y overlaps the trench 31Y in plan view. The dent 32Y has, for example, an arcuate and curved surface.

The wiring substrate 10 may be used in a state flipped upside down or may be arranged at any angle.

### Method for Manufacturing Wiring Substrate 10

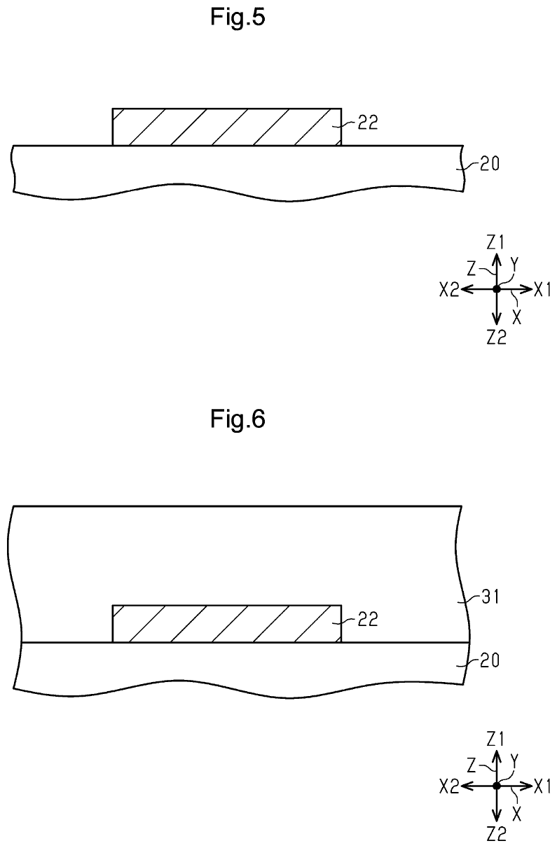

A method for manufacturing the wiring substrate 10 will now be described with reference to FIGS. 5 to 15. In particular, a method for manufacturing the insulating layer 31, the via hole 31X, the trench 31Y, the via wiring 41, the conductive layer 42, and the wiring layer 32 will be described. To facilitate understanding, portions that will become elements of the wiring substrate 10 are given the same reference characters as the final elements.

First, in the step illustrated in FIG. 5, a structural body in which the wiring layer 22 is formed on the upper surface of the core substrate 20 is prepared. This structural body may be manufactured by a known process. Thus, the process will not be described in detail.

In the step illustrated in FIG. 6, the insulating layer 31 is formed on the upper surface of the core substrate 20 to entirely cover the wiring layer 22. For example, when an insulating resin film is used as the insulating layer 31, the upper surface of the core substrate 20 is laminated with the insulating resin film. The insulating resin film is heated at a curing temperature or higher (e.g., approximately 130° C. to 200° C.) while being pressed so that the insulating resin film is cured to form the insulating layer 31. The insulating resin film may be, for example, a film of a thermosetting resin having an epoxy resin as a main component. When a liquid or a paste of insulating resin is used as the insulating layer 31, the liquid or paste of insulating resin is applied to the upper surface of the core substrate 20 by a spin coating process or the like. The applied insulating resin is heated at a curing temperature or higher so that the insulating resin is cured to form the insulating layer 31. The liquid or paste of insulating resin may be, for example, a thermosetting resin having an epoxy resin as a main component.

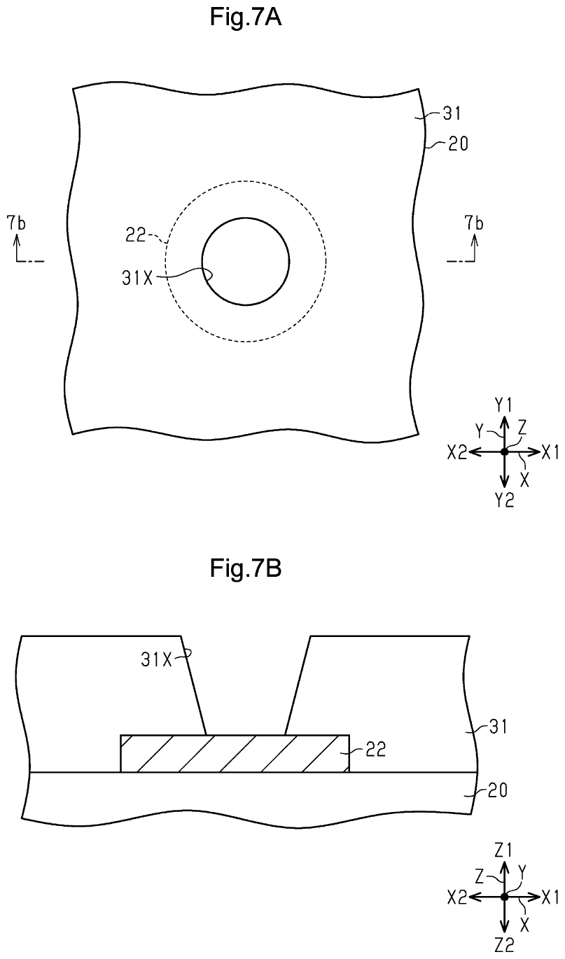

In the step illustrated in FIGS. 7A and 7B, the via hole 31X is formed in the insulating layer 31 to expose part of the upper surface of the wiring layer 22. The via hole 31X may be formed by, for example, irradiating the insulating layer 31 with a laser beam. That is, the via hole 31X may be formed by laser cutting. The laser beam source used for emission of the laser beam may be, for example, a CO₂ laser or a UV-YAG laser.

The laser beam emitted toward the insulating layer 31 has, for example, an intensity (energy) that is sufficient for forming the via hole 31X having a desired diameter with a single shot, or a single emission. For example, a laser beam having the energy required to form the via hole 31X in an insulating layer 31 that does not include an inorganic filler needs to be emitted multiple times (e.g., three times or more) to form the via hole 31X in an insulating layer 31 that includes an inorganic filler. Accordingly, a laser beam having the energy corresponding to the multiple emissions of the laser beam is used in a single shot. Such emission of the laser beam toward the insulating layer 31 forms the via hole 31X that extends through the insulating layer 31 in the thickness-wise direction and exposes part of the upper surface of the wiring layer 22.

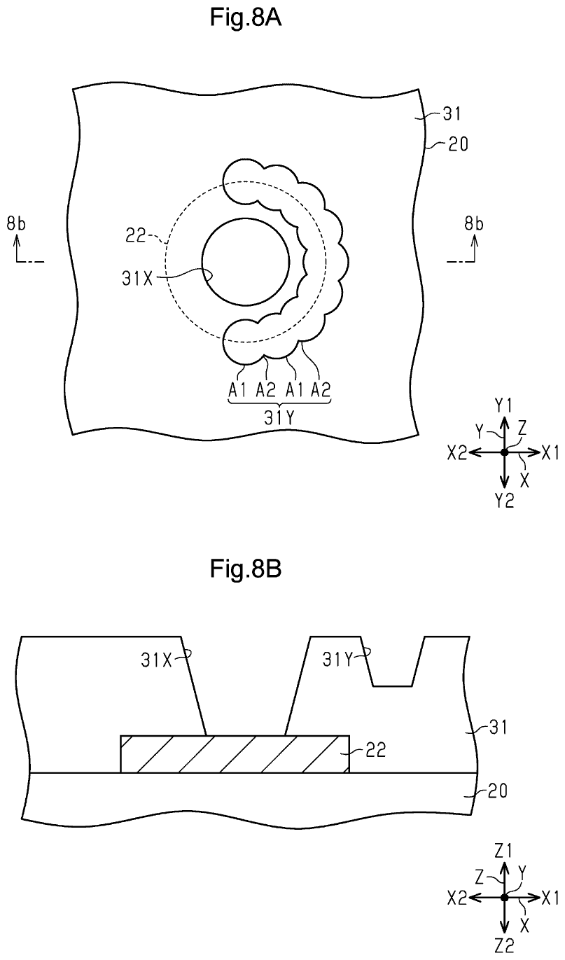

In the step illustrated in FIGS. 8A and 8B, the trench 31Y is formed peripheral to the via hole 31X. The trench 31Y is recessed from the upper surface of the insulating layer 31 toward the core substrate 20. The trench 31Y is separated from the via hole 31X in the first direction X1. The trench 31Y is shallower than the via hole 31X. The trench 31Y may be formed by, for example, laser cutting. The laser beam source used for the laser cutting may be, for example, a CO₂ laser or a UV-YAG laser.

As illustrated in FIG. 8A, for example, the trench 31Y extends in the lengthwise direction that is parallel to the circumferential direction of the via hole 31X in plan view. Such a trench 31Y is formed by, for example, sequentially performing laser cutting in the lengthwise direction of the trench 31Y so that each shot of the laser beam partially overlaps an adjacent shot. This connects multiple shot portions to form a single trench 31Y. In this case, the formed trench 31Y has the contour including the projections A1 and the recesses A2 in plan view, and the bottom surface of the trench 31Y includes the trench parts B1 and B2 (refer to FIG. 4). The laser beam power used in the laser cutting for forming the trench 31Y is, for example, less than the laser beam power used for forming a single via hole 31X.

The via hole 31X and the trench 31Y may be formed simultaneously by adjusting the conditions of the laser beam emission or the like in the laser cutting.

When the via hole 31X is formed by laser cutting, a desmear process is subsequently performed to remove resin smears from the surface of the wiring layer 22 exposed from the via hole 31X.

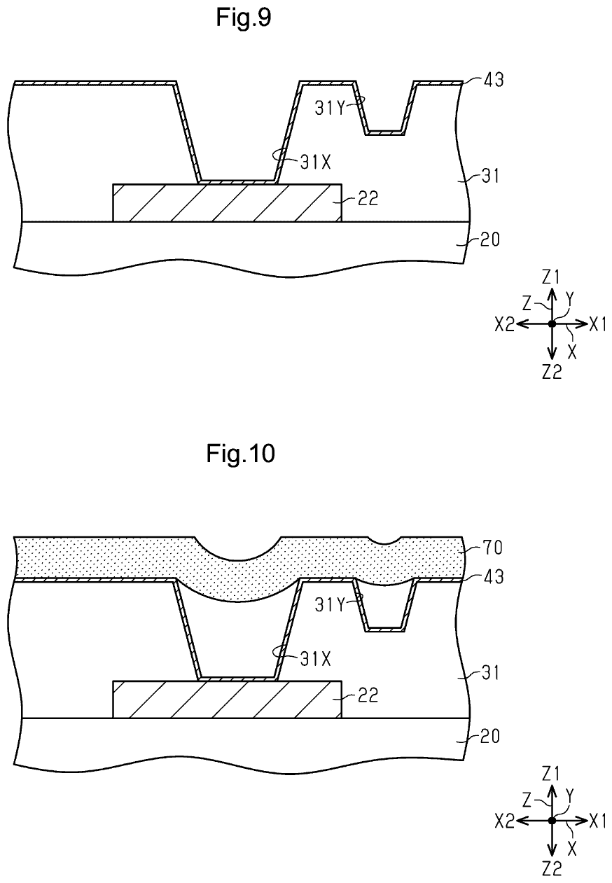

In the step illustrated in FIG. 9, the metal film 43 is formed to continuously cover the upper surface of the insulating layer 31, the inner surface of the via hole 31X, and the inner surface of the trench 31Y. The metal film 43 continuously covers the entire upper surface of the insulating layer 31, the entire wall surface of the via hole 31X, the entire upper surface of the wiring layer 22 exposed from the via hole 31X, the entire wall surface of the trench 31Y, and the entire bottom surface of the trench 31Y. The metal film 43 may be formed by, for example, an electroless plating process. The metal film 43 may be formed by, for example, an electroless copper plating process using a plating solution that includes a mixture of copper sulfate, sodium hydroxide, carboxylate, nickel sulfate, and formaldehyde. Alternatively, the metal film 43 may be formed by, for example, a sputtering process or a vapor deposition process.

In the step illustrated in FIG. 10, a resist layer 70 is formed on the metal film 43. The resist layer 70 covers the entire upper surface of the metal film 43. In this case, for example, a portion of the resist layer 70 overlapping the via hole 31X in plan view and a portion of the resist layer 70 overlapping the trench 31Y in plan view sag. The material of the resist layer 70 may include a photosensitive dry film resist. The dry film resist may be, for example, a dry film resist of a novolac-based resin or an acrylic-based resin. An example of a step of forming the resist layer 70 will now be described.

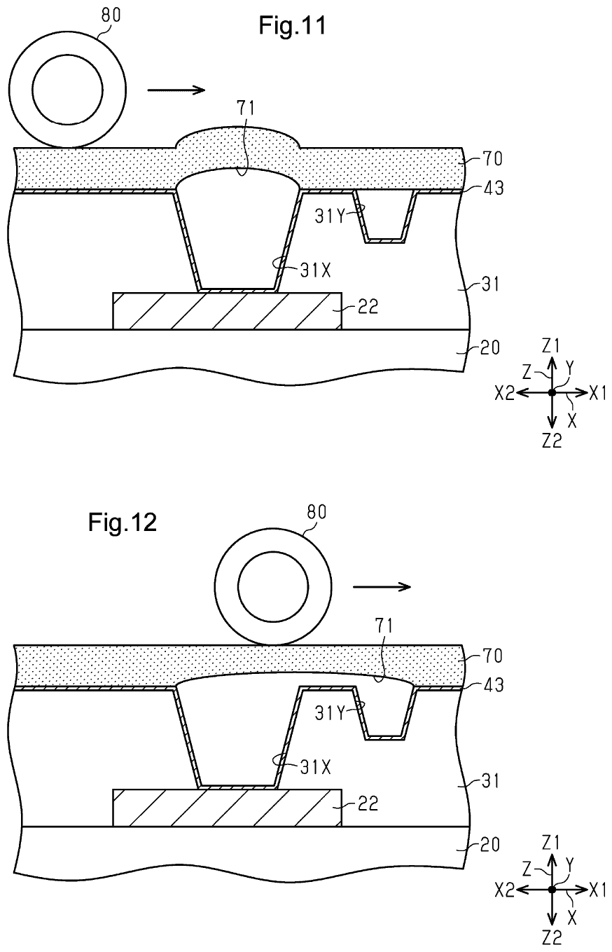

As illustrated in FIG. 11, first, the upper surface of the metal film 43 is laminated with the resist layer 70, which is a dry film resist. In this case, a void 71 (bubble) may be formed in the resist layer 70. In the example illustrated in FIG. 11, the void 71 is formed in a portion overlapping the via hole 31X in plan view.

Then, a roller 80 moving in the first direction X1 heats and presses the resist layer 70. In this step, the heated roller 80 applies pressure to the resist layer 70 toward the metal film 43. The present step is performed to improve the adhesion between the resist layer 70 and the metal film 43. However, if the void 71 is formed as described above, the heating by the roller 80 may expand the void 71. The expanded void 71 may be pushed out of the via hole 31X by the roller 80 in the first direction X1 in which the roller 80 is moved. The void 71 that is forced out of the via hole 31X in such a manner may cause separation of the resist layer 70 from the metal film 43. In other words, a cavity may be formed between the resist layer 70 and the metal film 43. If the cavity formed between the resist layer 70 and the metal film 43 spreads to an adjacent wiring formation region, short circuiting may occur between the via wiring 41 filling the via hole 31X (refer to FIG. 2) and the adjacent wiring. That is, the cavity between the resist layer 70 and the metal film 43 may cause short circuiting between adjacent wiring layers.

In this regard, the trench 31Y is formed peripheral to the via hole 31X in the present embodiment. The trench 31Y is separated from the via hole 31X in the first direction X1, which is the moving direction of the roller 80.

Accordingly, as illustrated in FIG. 12, when the heated roller 80 pushes the void 71 out of the via hole 31X in the first direction X1, the void 71 may be released into the trench 31Y. The trench 31Y traps the void 71 forced out by the roller 80, thereby restricting further spreading of the void 71 from the trench 31Y in the first direction X1. As a result, a cavity will not be formed between the resist layer 70 and the metal film 43 in a region located further in the first direction X1 from the trench 31Y.

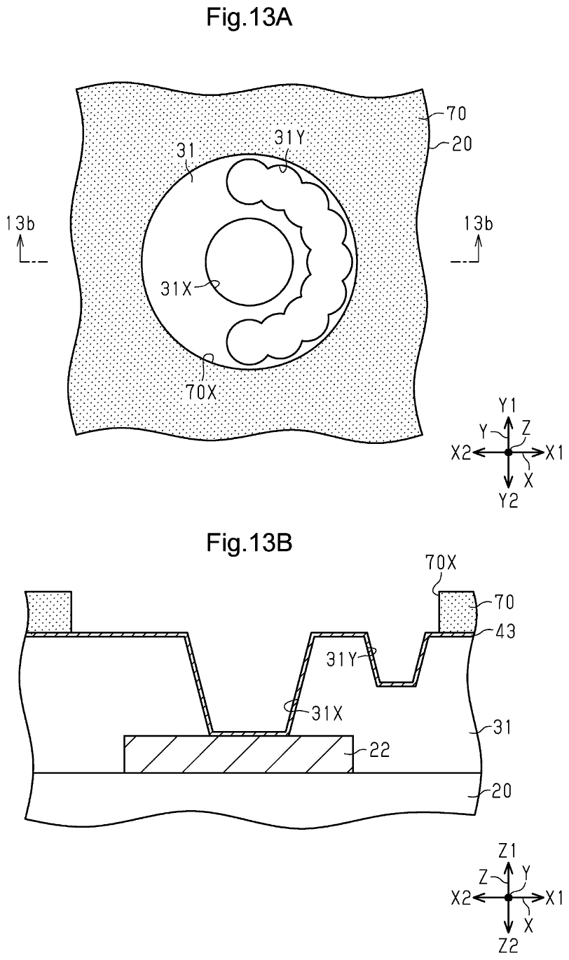

In the step illustrated in FIGS. 13A and 13B, an opening pattern 70X is formed in the resist layer 70 to expose the via hole 31X and the trench 31Y. As illustrated in FIG. 13A, the opening pattern 70X overlaps the entire via hole 31X in plan view. The opening pattern 70X overlaps the entire trench 31Y in plan view. As illustrated in FIG. 13B, the opening pattern 70X extends through the resist layer 70 in the thickness-wise direction. The opening pattern 70X may be formed by, for example, patterning the resist layer 70 through photolithography.

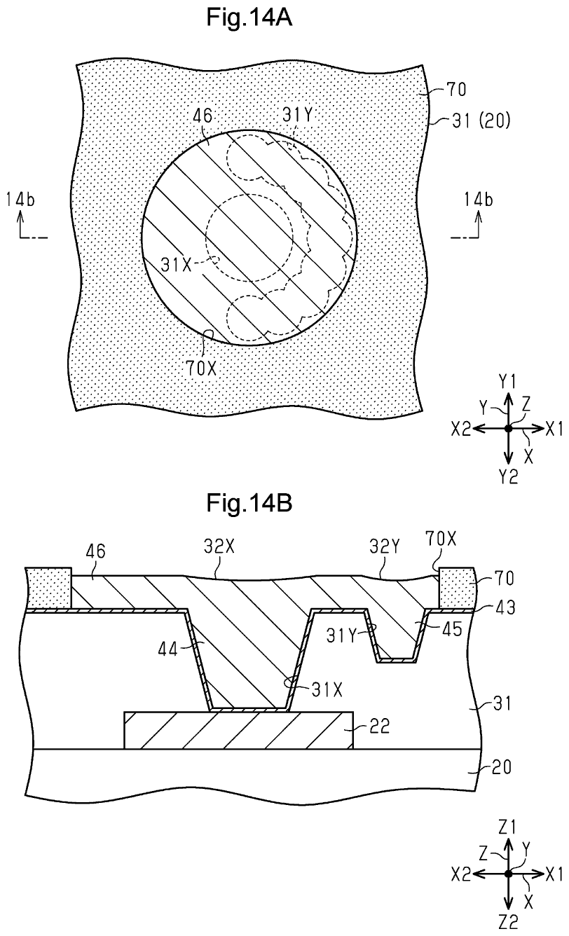

In the step illustrated in FIGS. 14A and 14B, electrolytic plating is performed on the metal film 43 using the resist layer 70 as a plating mask and the metal film 43 as a plating power feeding layer. That is, electrolytic plating (e.g., electrolytic copper plating) is performed on the upper surface of the metal film 43 exposed from the opening pattern 70X in the resist layer 70. This step forms the metal layer 44 covering the metal film 43 and filling the via hole 31X, and the metal layer 45 covering the metal film 43 and filling the trench 31Y. Further, this step forms the metal layer 46 in the opening pattern 70X. In this case, for example, the dents 32X and 32Y are formed in the upper surface of the metal layer 46 as illustrated in FIG. 14B. The metal layer 46 is formed to be continuous with and integrated with the metal layer 44 and the metal layer 45.

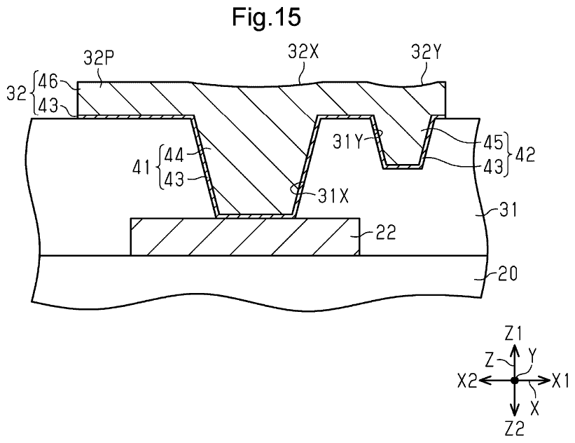

In the step illustrated in FIG. 15, the resist layer 70 illustrated in FIGS. 14A and 14B is removed using an alkaline stripping solution, such as an organic amine stripping solution, caustic soda, acetone, ethanol, or the like.

Then, etching is performed using the metal layer 46 as an etching mask to remove unnecessary portions of the metal film 43.

The manufacturing steps described above form the via wiring 41 including the metal film 43 and the metal layer 44 in the via hole 31X, and the conductive layer 42 including the metal film 43 and the metal layer 45 in the trench 31Y. Further, the wiring layer 32 including the metal film 43 and the metal layer 46 is formed on the insulating layer 31.

The present embodiment has the following advantages.

(1) The wiring substrate 10 includes the core substrate 20, the wiring layer 22, and the insulating layer 31. The wiring layer 22 is located on the upper surface of the core substrate 20. The insulating layer 31 is located on the upper surface of the core substrate 20 and covers the wiring layer 22. The wiring substrate 10 includes the via hole 31X and the trench 31Y. The via hole 31X extends through the insulating layer 31 in the thickness-wise direction and exposes the upper surface of the wiring layer 22. The trench 31Y is located in the upper surface of the insulating layer 31. The wiring substrate 10 includes the via wiring 41 and the conductive layer 42. The via wiring 41 fills the via hole 31X and is electrically connected to the wiring layer 22. The conductive layer 42 fills the trench 31Y. The wiring substrate 10 includes the wiring layer 32 electrically connected to the wiring layer 22 by the via wiring 41 and located on the upper surface of the insulating layer 31. The trench 31Y does not extend through the insulating layer 31 in the thickness-wise direction. The trench 31Y is located peripheral to the via hole X and is separated from the via hole. The trench 31Y overlaps the wiring layer 32 in plan view.

With this structure, the trench 31Y, which does not extend through the insulating layer 31 in the thickness-wise direction, that is, shallower than the via hole 31X, is arranged peripheral to the via hole 31X and is separated from the via hole 31X. Therefore, even if the void 71 is included in the resist layer 70, which is formed on the metal film 43, during the manufacturing process of the wiring substrate 10 or the like, the void 71 will not spread to an adjacent wiring formation region. When the roller 80 heats and applies pressure to the resist layer 70 in a state in which the void 71 is formed in a portion of the resist layer 70 overlapping the via hole 31X in plan view, the void 71 pushed out of the via hole 31X by the roller 80 in the planar direction is trapped by the trench 31Y. This restricts spreading of the void 71 outward from the trench 31Y. As a result, a cavity formed between the resist layer 70 and the metal film 43 will not extend to an adjacent wiring formation region located outward from the trench 31Y. This avoids occurrence of short circuiting between adjacent wiring layers caused by a cavity formed between the resist layer 70 and the metal film 43.

(2) The trench 31Y is shallower than the via hole 31X. Therefore, when laminating the upper surface of the metal film 43 with the resist layer 70, the void 71 will not be formed in a portion of the resist layer 70 overlapping the trench 31Y in plan view. In other words, the trench 31Y will not cause formation of the void 71.

(3) The trench 31Y is separated from the via hole 31X in the first direction X1 in plan view. With this structure, the trench 31Y traps the void 71 pushed out of the via hole 31X by the roller 80 moving in the first direction X1 during the manufacturing process of the wiring substrate 10 or the like. This limits further spreading of the void 71 from the trench 31Y in the first direction X1. As a result, a cavity formed between the resist layer 70 and the metal film 43 will not extend to an adjacent wiring formation region located further in the first direction X1 from the trench 31Y. This avoids occurrence of short circuiting between adjacent wiring layers caused by a cavity formed between the resist layer 70 and the metal film 43.

(4) The dimension of the trench 31Y in the second direction Y1 is greater than or equal to the diameter of the via hole 31X. With this structure, the trench 31Y faces the via hole 31X over the entire length of the via hole 31X in the second direction Y1. Therefore, the trench 31Y traps the void 71 pushed out of the via hole 31X in the first direction X1. This avoids occurrence of short circuiting between adjacent wiring layers.

(5) If the trench 31Y intermittently faced the circumference of the via hole 31X, the void 71 may spread beyond the trench 31Y further in the first direction X1 through a portion that does not include the trench 31Y. In contrast, in the wiring substrate 10 of the present embodiment, the trench 31Y continuously faces the circumference of the via hole 31X. Therefore, the trench 31Y included in a region facing the via hole 31X in the first direction X1 restricts spreading of the void 71 further in the first direction X1 from the trench 31Y.

(6) The trench 31Y is shallower than the via hole 31X. Thus, the trench 31Y is less likely to cause formation of the void 71 than the via hole 31X is. Nonetheless, as compared to a solid part of the resist layer 70 that does not include the trench 31Y, the void 71 is more likely to be formed in a part where the trench 31Y is located. Accordingly, in the wiring substrate 10 of the present embodiment, the trench 31Y faces only part of the circumference of the via hole 31X. With this structure, the trench 31Y is formed in a relatively small region, and is thus less likely to cause formation of the void 71.

(7) The trench 31Y has a contour including projections and recesses in plan view. This structure increases the surface area defined by the contour of the trench 31Y so that the contact surface area between the wall surface of the trench 31Y and the peripheral surface of the conductive layer 42 is increased. This improves the adhesion between the insulating layer 31 and the conductive layer 42 in the trench 31Y.

(8) The trench 31Y includes the first trench part B1 and the second trench part B2 that is continuous with the first trench part B1 and is shallower than the first trench part B1. With this structure, the bottom surface of the trench 31Y includes irregularities (refer to FIG. 4). This increases the area of the bottom surface of the trench 31Y so that the contact surface area between the bottom surface of the trench 31Y and the lower surface of the conductive layer 42 is increased. As a result, the adhesion between the insulating layer 31 and the conductive layer 42 in the trench 31Y is improved.

### Modified Examples

The above embodiment may be modified as described below. The above embodiment and the following modifications may be combined as long as the combined modifications remain technically consistent with each other.

The structure of the trench 31Y in the above embodiment may be changed.

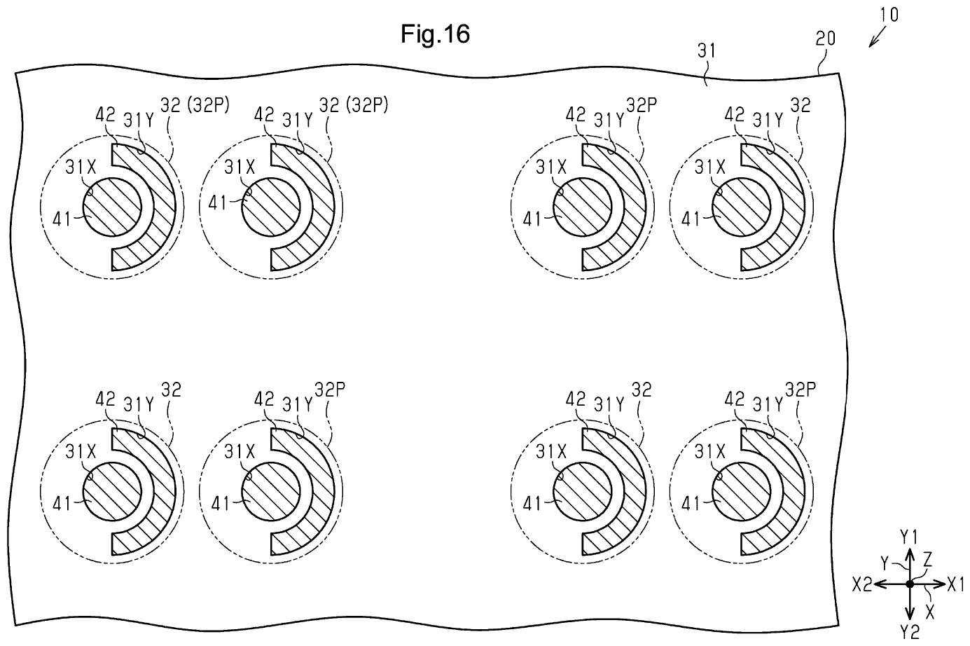

As illustrated in FIG. 16, for example, the contour of the trench 31Y may be changed to a shape that does not include projections or recesses. In FIG. 16, the trench 31Y facing the via hole 31X has a contour that extends in an arcuate manner along the circumference of the via hole 31X in plan view.

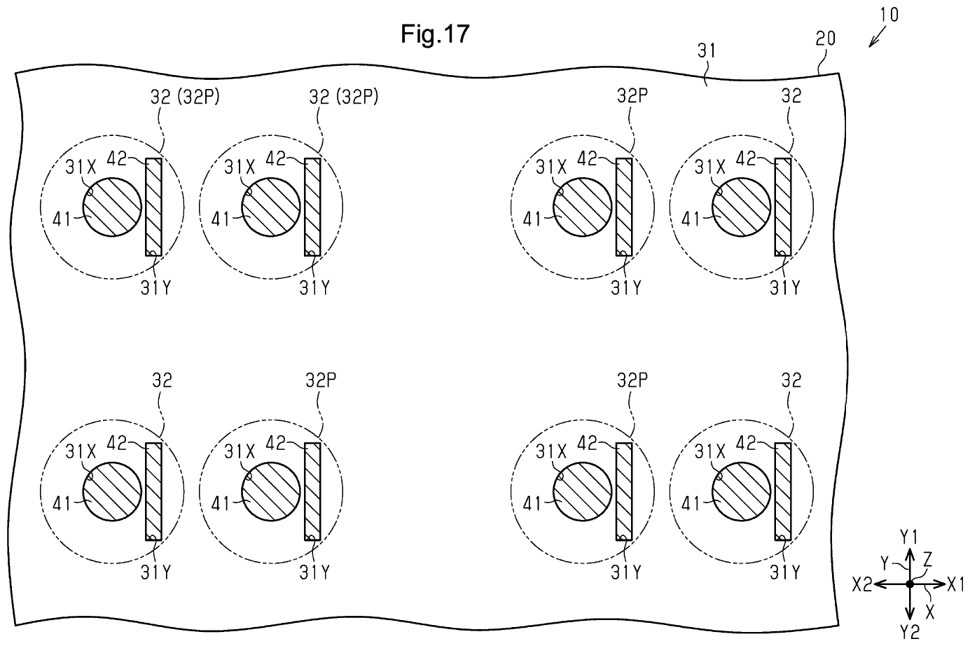

As illustrated in FIG. 17, for example, the planar shape of the trench 31Y may be changed to a linear shape extending in the second direction Y1. In this case, the lengthwise direction of the trench 31Y coincides with the second direction Y1. In the present modified example, it is preferred that the dimension of the trench 31Y in the second direction Y1 be greater than or equal to the diameter of the via hole 31X.

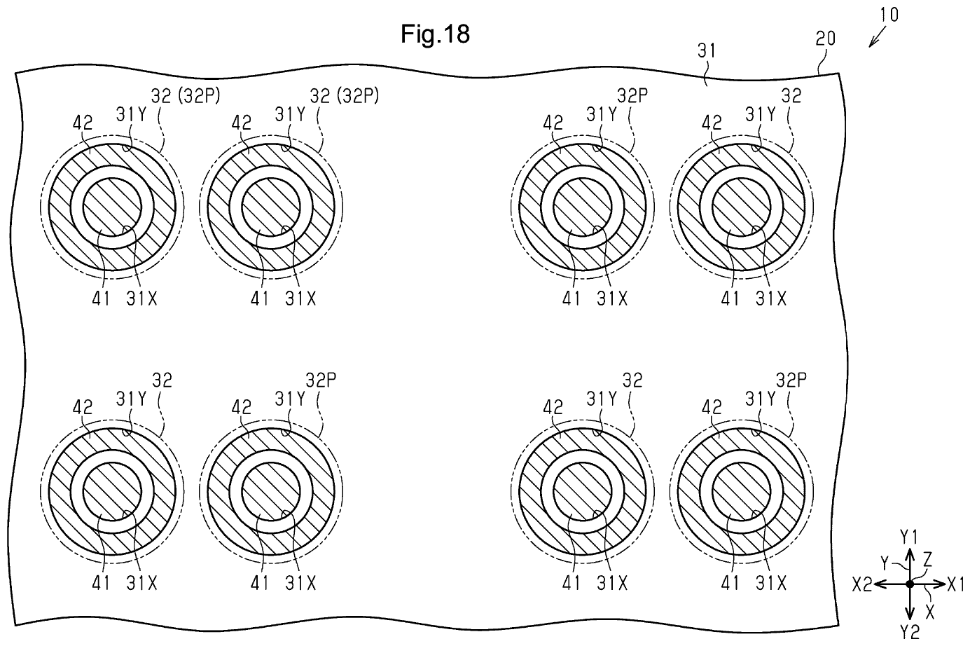

As illustrated in FIG. 18, for example, the trench 31Y may face the via hole 31X along the entire circumference of the via hole 31X in plan view. In this case, the trench 31Y entirely surrounds the circumference of the via hole 31X in plan view. In the present modified example, the planar shape of the trench 31Y is, for example, annular.

In the above embodiment, the bottom surface of the trench 31Y does not have to include irregularities.

In the above embodiment, the wall surface of the trench 31Y may extend orthogonal to the upper surface of the insulating layer 31 in cross-sectional view.

In the above embodiment, the insulating layer 31 includes the trenches 31Y, and the insulating layer 51 includes the trenches 51Y. However, the arrangement of the trenches 31Y and 51Y may be changed. For example, the insulating layer 33 may include the trenches 31Y. Furthermore, the insulating layer 53 may include the trenches 51Y. Alternatively, the trenches 51Y may be omitted from the insulating layer 51.

In the above embodiment, the insulating layer 31 includes multiple trenches 31Y, and the insulating layer 51 includes multiple trenches 51Y. However, for example, the insulating layer 31 may include a single trench 31Y, and the insulating layer 51 may include a single trench 51Y.

In the above embodiment, the trench 31Y is formed for each of the via holes 31X. However, for example, the trench 31Y may be formed for only some of the via holes 31X.

In the above embodiment, the planar shape of the via hole 31X may be changed.

In the above embodiment, the wall surface of the via hole 31X may extend orthogonal to the upper surface of the insulating layer 31 in cross-sectional view.

In the above embodiment, the structure of the wiring layer 32 may be changed. For example, at least one of the dents 32X and 32Y may be omitted.

In the above embodiment, the metal film 43 is a seed layer having a single-layer structure. Instead, the metal film 43 may be a seed layer having a multi-layer structure (e.g., double-layer structure). A seed layer having a double-layer structure includes, for example, a stack structure of a titanium (Ti) layer and a Cu layer.

In the method for manufacturing the wiring substrate 10 of the above embodiment, the via holes 31X are formed by laser cutting. Instead, the via holes 31X may be formed by a process other than laser cutting.

In the above method for manufacturing the wiring substrate 10 of the embodiment, the trenches 31Y are formed by laser cutting. Instead, the trenches 31Y may be formed by a process other than laser cutting.

In the above embodiment, the structure of the wiring substrate 10 may be changed. For example, the wiring layers 32 and 34 in the wiring structure 30 may be replaced by any number of wiring layers and may be laid out in any manner. Also, the insulating layers 31 and 33 may be replaced by any number of insulating layers. For example, the wiring layers 52 and 54 in the wiring structure 50 may be replaced by any number of wiring layers and may be laid out in any manner. Also, the insulating layers 51 and 53 may be replaced by any number of insulating layers. For example, the wiring substrate 10 may be changed to a coreless substrate that does not include the core substrate 20. In this case, for example, a first insulating layer is formed on the lower surface of the insulating layer 31, instead of the core substrate 20.

In the above embodiment, the solder resist layers 35 and 55 may be omitted.

In the above embodiment, the wiring substrate 10 may be applied to a wiring substrate used in a package, such as a chip size package (CSP), a small outline non-lead package (SON), or the like.

### CLAUSES

This disclosure further encompasses the following embodiments.

1. A method for manufacturing a wiring substrate, the method including:
forming a first wiring layer on an upper surface of a first insulating layer;
forming a second insulating layer on the upper surface of the first insulating layer to cover the first wiring layer;
forming a via hole extending through the second insulating layer in a thickness-wise direction to expose an upper surface of the first wiring layer;
forming a trench in an upper surface of the second insulating layer, the trench not extending through the second insulating layer in the thickness-wise direction;
forming a metal film continuously covering the upper surface of the second insulating layer, an inner surface of the via hole, and an inner surface of the trench;
forming a resist layer on an upper surface of the metal film;
forming an opening in the resist layer to expose the via hole and the trench;
forming a via wiring filling the via hole, a conductive layer filling the trench, and a second wiring layer covering the upper surface of the second insulating layer by an electrolytic plating process using the resist layer as a plating mask; and
removing the resist layer, where:
the forming the resist layer includes
   laminating the upper surface of the metal film with the resist layer that is a dry film resist, and
   heating and pressing the resist layer with a roller that is moved in a first direction; and
the trench is arranged peripheral to the via hole and separated from the via hole in the first direction in plan view.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

1. A wiring substrate, comprising:
a first insulating layer;
a first wiring layer located on an upper surface of the first insulating layer;
a second insulating layer located on the upper surface of the first insulating layer and covering the first wiring layer;
a via hole extending through the second insulating layer in a thickness-wise direction and exposing an upper surface of the first wiring layer;
a trench recessed from an upper surface of the second insulating layer;
a via wiring filling the via hole and electrically connected to the first wiring layer;
a conductive layer filling the trench; and
a second wiring layer electrically connected to the first wiring layer by the via wiring and located on the upper surface of the second insulating layer, wherein
the trench does not extend through the second insulating layer in the thickness-wise direction, and
the trench is arranged peripheral to the via hole and separated from the via hole, and the trench overlaps the second wiring layer in plan view.

2. The wiring substrate according to claim 1, wherein the trench is adjacent to the via hole across the upper surface of the second insulating layer in plan view.

3. The wiring substrate according to claim 2, wherein a length of the upper surface of the second insulating layer from the via hole to the trench in a radial direction of the via hole in plan view is smaller than a diameter of an upper end of the via hole.

4. The wiring substrate according to claim 1, wherein the trench is shallower than the via hole.

5. The wiring substrate according to claim 1, wherein
the trench is separated from the via hole in a first direction in plan view, and
the trench has a dimension in a second direction orthogonal to the first direction in plan view that is greater than or equal to a dimension of the via hole in the second direction.

6. The wiring substrate according to claim 5, wherein:
the wiring substrate includes a plurality of via holes and a plurality of trenches, the via hole being one of the plurality of via holes, and the trench being one of the plurality of trenches;
each of the plurality of trenches is arranged for a corresponding one of the plurality of via holes; and
each of the plurality of trenches is separated from the corresponding one of the plurality of via holes in the first direction.

7. The wiring substrate according to claim 5, wherein
the via hole has a circular planar shape,
the dimension of the trench in the second direction is greater than or equal to a diameter of the via hole,
the trench continuously faces a circumference of the via hole in plan view, and
the trench is arcuate along the circumference of the via hole in plan view.

8. The wiring substrate according to claim 7, wherein the trench faces only part of the circumference of the via hole in plan view.

9. The wiring substrate according to claim 1, wherein
the trench has a contour including projections and recesses in plan view, and
the projections and the recesses are curved.

10. The wiring substrate according to claim 9, wherein
the projections and the recesses are alternately and continuously arranged one by one along a circumference of the via hole in plan view.

11. The wiring substrate according to claim 1, wherein the trench includes a first trench part and a second trench part that is continuous with the first trench part and shallower than the first trench part.

12. The wiring substrate according to claim 1, wherein
the second wiring layer includes a pad, and
the trench overlaps the pad in plan view.

13. The wiring substrate according to claim 1, further comprising:
a metal film continuously covering the upper surface of the second insulating layer, an inner surface of the via hole, and an inner surface of the trench;
a first metal layer covering the metal film and filling the via hole;
a second metal layer covering the metal film and filling the trench; and
a third metal layer formed integrally with the first metal layer and the second metal layer and located on the first metal layer and the second metal layer, wherein:
the via wiring includes the metal film covering the inner surface of the via hole, and the first metal layer,
the conductive layer includes the metal film covering the inner surface of the trench, and the second metal layer, and
the second wiring layer includes the metal film covering the upper surface of the second insulating layer, and the third metal layer.
